(19) United States
(12) Patent Application Publication
(10) Pub. No.: US 2023/0081182 A1
(43) Pub. Date: Mar. 16, 2023

(54) APPARATUS FOR TREATING SUBSTRATE AND METHOD FOR TREATING SUBSTRATE

(71) Applicant: SEMES CO., LTD., Cheonan-s (KR)

(72) Inventors: Yoon Seok CHOI, Suwon-si (KR); Yun Sang KIM, Seongnam-si (KR); Sun Wook JUNG, Hwaseong-si (KR)

(73) Assignee: SEMES CO., LTD., Cheonan-s (KR)

(21) Appl. No.: 17/939,174

(22) Filed: Sep. 7, 2022

(30) Foreign Application Priority Data
Sep. 8, 2021 (KR) 10-2021-0119975

(51) Int. Cl. H01J 37/32; H01L 21/306

(52) U.S. Cl. CPC H01J 37/32311; H01J 37/3222; H01J 37/32302; H01L 21/30621; H01J 37/32522; H01J 2237/327; H01L 29/2003

(57) ABSTRACT

The inventive concept provides a substrate treating apparatus. In an embodiment the substrate treating apparatus includes a process chamber having a treating space therein for treating a substrate; a substrate support unit configured to support the substrate in the treating space; and a microwave application unit configured to apply a microwave to the treating space, and wherein the microwave application unit comprises a microwave power generator based on a solid state device.

### CROSS-REFERENCE TO RELATED APPLICATIONS

A claim for priority under 35 U.S.C. § 119 is made to Korean Patent Application No. 10-2021-0119975 filed on Sep. 8, 2021, in the Korean Intellectual Property Office, the entire contents of which are hereby incorporated by reference.

### BACKGROUND

Embodiments of the inventive concept described herein relate to a substrate treating apparatus and a substrate treating method.

In a substrate heating process among a substrate treating process, a microwave may be used. The microwave is generated by using a magnetron. A microwave which is transmitted to a substrate after being generated by using the magnetron has a bad temperature uniformity, because there is a large temperature difference between a hot spot and a cold spot.

### SUMMARY

Embodiments of the inventive concept provide a substrate treating apparatus and a substrate treating method for efficiently treating a substrate.

Embodiments of the inventive concept provide a substrate treating apparatus for performing a plasma treatment and a heating treatment in one chamber with respect to a substrate.

Embodiments of the inventive concept provide a substrate treating apparatus and a substrate treating method having a high temperature uniformity, with respect to treating a substrate by heating the substrate with a microwave.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a process chamber having a treating space therein for treating a substrate; a substrate support unit configured to support the substrate in the treating space; and a microwave application unit configured to apply a microwave to the treating space, and wherein the microwave application unit comprises a microwave power generator based on a solid state device.

In an embodiment, the solid state device comprises a gallium nitride (GaN) device.

In an embodiment, the microwave power generator may shift or sweep a frequency of the microwave.

In an embodiment, the microwave power generator is capable of sweeping a microwave having a first bandwidth between a first frequency and a second frequency which is higher than the first frequency.

In an embodiment, the microwave power generator sweeps the microwave having the first bandwidth a plural number of times.

In an embodiment, the microwave power generator sweeps a microwave having a first bandwidth between a first frequency and a second frequency which is higher than the first frequency, and a sum of a plurality of modes is a heating profile, and wherein the plurality of modes are determined in a different number according to a shape of the treating space.

In an embodiment, the microwave power generator sweeps a microwave having a first bandwidth between a first frequency and a second frequency which is higher than the first frequency, and a sum of a plurality of modes is a heating profile, and wherein the plurality of modes are determined in a different number according to a width of the first bandwidth.

In an embodiment, the microwave application unit includes: a microwave antenna in a plate shape positioned above the substrate support unit; a dielectric plate positioned on top of and beneath the microwave antenna; and an antenna rod transmitting a microwave generated at the microwave power generator to the microwave antenna.

In an embodiment, the microwave application unit functions as a heating source for transmitting an energy for heating to the substrate.

In an embodiment, the substrate treating apparatus further includes a gas supply unit for supplying a reaction gas to the treating space, and wherein microwave application unit functions as a plasma source for generating a plasma from the reaction gas.

The inventive concept provides a substrate treating apparatus. The substrate treating apparatus includes supporting a substrate in a treating space of a process chamber; and applying a microwave to the treating space with a plurality of frequency sweeping.

In an embodiment, the microwave is generated by a microwave power generator based on a solid state device.

In an embodiment, the solid state device comprises a gallium nitride (GaN) device.

In an embodiment, the frequency sweeping of the microwave sweeps a microwave having a first bandwidth between a first frequency and a second frequency which is higher than the first frequency.

In an embodiment, the microwave is provided sweeping the microwave having the first bandwidth a plural number of times.

In an embodiment, the microwave sweeps a microwave having a first bandwidth between a first frequency and a second frequency which is higher than the first frequency, and a sum of a plurality of modes is a heating profile, and wherein the plurality of modes are determined in a different number according to a shape of the treating space.

In an embodiment, the microwave sweeps a microwave having a first bandwidth between a first frequency and a second frequency which is higher than the first frequency, and a sum of a plurality of modes is a heating profile, and wherein the plurality of modes are determined in a different number according to a width of the first bandwidth.

In an embodiment, the substrate is heated by a transmission of the microwave.

In an embodiment, a microwave which is different from the microwave is transmitted to the treating space to excite a reaction gas within the treating space to a plasma.

The inventive concept provides a substrate treating apparatus. The substrate treating apparatus includes a process chamber having a treating space therein for treating a substrate; a substrate support unit configured to support the substrate in the treating space; a microwave application unit configured to apply a microwave to the treating space, and wherein the microwave application unit comprises a microwave power generator based on a gallium nitride (GaN) solid state device, and wherein the microwave power generator sweeps a plurality of target sweeping frequencies existing at a first bandwidth between a first frequency and a second frequency which is higher than the first frequency, and wherein the number of target sweeting frequencies is determined differently according to a shape of the treating space y and a width of the first bandwidth.

According to an embodiment of the inventive concept, a substrate may be efficiently treated.

According to an embodiment of the inventive concept, a substrate may be plasma treated and heat treated in one chamber.

According to an embodiment of the inventive concept, a temperature uniformity is high with respect to heat treating a substrate with a microwave.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view of a substrate treating apparatus according to an embodiment of the inventive concept.

FIG. 2 is an example of a broad band microwave source.

### DETAILED DESCRIPTION

Hereinafter, embodiments of this invention will be described in detail with reference to the accompanying drawings so that those of ordinary skill in the technical field to which this invention belongs can easily implement this invention. However, the inventive concept may be implemented in various different forms and is not limited to the embodiments described herein. In addition, in describing a correct embodiment of the inventive concept in detail, when it is determined that a detailed description of related known functions or configurations may unnecessarily obscure the gist of the inventive concept, the detailed description thereof will be omitted. In addition, a same sign is used throughout the drawing for parts with similar functions and actions.

To “include” and “comprise” a component means that it may include more other components, not excluding other components unless otherwise stated. Specifically, the term “include”, “comprise” and “have” should be understood to designate that there are features, numbers, steps, operations, components, or a combination thereof described in the specification, and do not preclude the presence or addition of one or more other features or numbers, steps, operations, components, or combinations thereof.

The singular expression includes plural expressions unless the context clearly implies otherwise. In addition, shapes and sizes of elements in the drawings may be exaggerated for clearer explanation.

The term “and/or” includes any one of the listed items and all combinations of one or more. In addition, in the present specification, the term “connected” means not only a case where member A and member B are directly connected, but also a case where member C is interposed between member A and member B to indirectly connect member A and member B.

Embodiments of the inventive concept may be modified in various forms, and the scope of the inventive concept should not be construed as being limited to the following embodiments. The embodiment of the inventive concept is provided to more fully explain the inventive concept on to those with average knowledge in the art. Therefore, the shape of the elements in the drawing has been exaggerated to emphasize a clearer explanation.

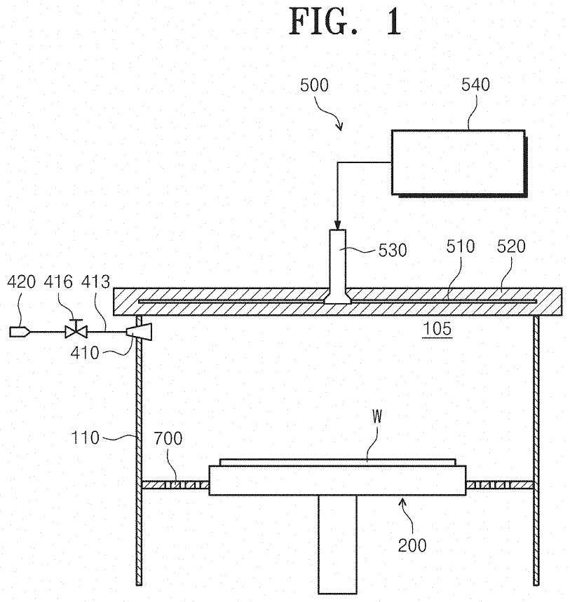

FIG. 1 is a cross-sectional view illustrating a substrate treating apparatus according to an embodiment (a first exemplary embodiment) of the inventive concept. Referring to FIG. 1, the substrate treating apparatus according to an embodiment of the inventive concept may be explained. The substrate treating apparatus includes a process chamber 110, a substrate support unit 200, a gas supply unit 400, a microwave application unit 500, and an exhaust baffle 700.

The process chamber 110 provides a treating space 105 for treating a substrate therein. The process chamber may have a circular cylindrical form. An opening (not shown) is provided at a sidewall of the process chamber 110. The opening may be provided as an entrance at which the substrate W may be taken in and taken out. The entrance may be opened and closed by a door (not shown). An atmosphere of the treating space 105 is exhausted through the exhaust baffle 700 provided at a bottom of the process chamber 110. The exhaust baffle 700 may be connected to an exhaust pump (not shown).

The substrate support unit 200 supports the substrate W in the treating space. The substrate support unit 200 may be provided as an electrostatic chuck supporting the substrate W using an electrostatic force. Alternatively and/or additionally, the substrate support unit 200 may support the substrate W using various methods such as a mechanical clamping.

The gas supply unit 400 supplies a reaction gas to the inner space 105. The gas supply unit includes a gas nozzle 410, a gas supply source 420, and a gas supply line 413. The gas nozzle 410 is provided at a sidewall of the process chamber 110. The gas nozzle is connected through the gas supply source 420 and the gas supply line 413. The gas nozzle supplies the reaction gas.

The microwave application unit 500 includes a microwave antenna 510, a dielectric plate 520, an antenna rod 530, and a power generator 540. The microwave application unit 500 may function as a plasma source for generating a plasma from a process gas. Also, the microwave application unit 500 may function as an annealing source for annealing the substrate.

The microwave antenna 510 may have a plate in a circular form. Hereinafter, the microwave antenna 510 may be referred to as antenna plate. A plurality of slot holes (not shown) may be formed at the microwave antenna 510, and slot holes (not shown) provide a path through which the microwaves transmit.

The dielectric plate 520 is positioned at a top and a bottom of the microwave antenna 510. In some embodiments, the microwave antenna 510 may be embedded within the dielectric plate 520. In some embodiments, the microwave antenna 510 may be disposed on a top surface of the dielectric plate 520. In some embodiments, the microwave antenna 510 may be disposed on a bottom surface of the dielectric pate 520. The dielectric plate 520 may be made of and/or comprise a dielectric such as an alumina and a quartz.

The antenna rod 530 may have a cylindrical rod. The antenna rod 530 is positioned with its lengthwise direction in an up/down direction. A bottom end of the antenna rod 530 is connected to the antenna plate 510. A center of the antenna plate 510 is inserted and fixed to the bottom of the antenna rod 530. A microwave applied from the power generator 540 is transmitted to the antenna plate 510.

The power generator 540 is provided as a microwave power generator based on a solid state device. In an embodiment, the power generator 540 is provided as a microwave power generator based on a gallium nitride (GaN). In an embodiment, the power generator 540 based on the gallium nitride (GaN) has a bandwidth which is narrow, and is provided with a function capable of performing a frequency shift or a frequency sweep. The frequency sweep is, for example, sweeping a microwave with a narrow band (e.g., 1 Hz) for a set time (e.g., 1 second) from a lower limit frequency to an upper limit frequency (e.g., 2.4 GHz to 2.5 GHz) of a specific band.

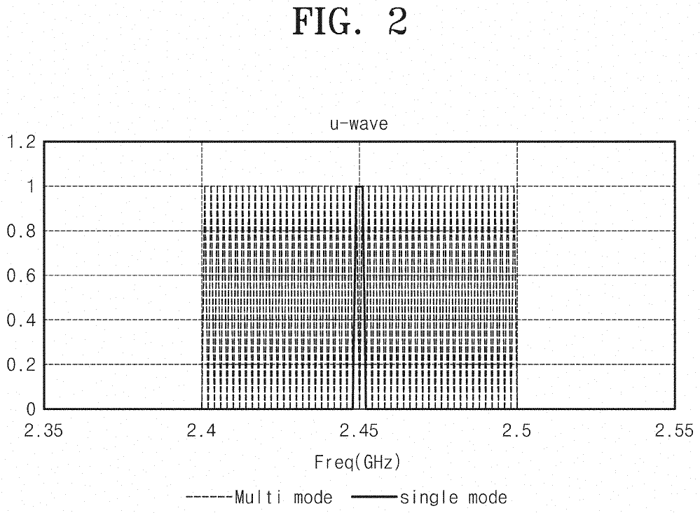

For example, it is assumed that a broadband microwave source as shown in a graph of FIG. 2 is used. A center frequency is 2.45 GHz and it is a broadband that can frequency shift from 2.4 GHz to 2.5 GHz.

A cavity is defined by the inner space 105 of the process chamber 110.

In an embodiment, assuming that the cavity is a box shape with a width (W, a diameter of a left to a right) of 29.7 cm, a depth (D, a diameter of a front to a back) of 36.6 cm, and a height (H) of 30.2 cm, a TEₘₙ₁ in a TE mode is derived as shown in [Table 1] below under a condition of frequency sweeping a 2.4 GHz to 2.5 GHz band. A total of six TE modes are derived. A sum of six heating profiles corresponding to each mode becomes a final heating profile. As a result, hot spots and cold spots are mixed to improve a heating uniformity.

The TE mode when assuming that the cavity is a
box shape with a width (W) of 29.7 cm, a depth
(D) of 36.6 cm, and a height (H) of 30.2 cm

| TE mode | Frequency |
|---|---|
| (mnl) | (GHz) |
| 431 | 2.4092 |
| 243 | 2.4331 |
| 342 | 2.4417 |
| 333 | 2.4534 |
| 060 | 2.4573 |
| 252 | 2.4895 |

As another example, assuming that the cavity is a cylindrical shape with a radius (R) of 25 cm and a depth (D) of 25 cm, a TMₘₙ₁ in a TM mode and a TEₘₙ₁ mode in a TE mode are derived as shown in [Table 2] below under a condition of frequency sweeping a 2.4 GHz to 2.5 GHz band. A total of six TM modes are derived, and a total of four TE modes are derived. The TM mode and the TE mode are determined according to a shape of the cavity. A sum of ten heating profiles corresponding to each mode becomes a final heating profile. As a result, hot spots and cold spots are mixed to improve the heating uniformity.

| TM mode | Frequency | TE mode | Frequency |
|---|---|---|---|
| (mnl) | (GHz) | (mnl) | (GHz) |
| 330 | 2.4847 | 430 | 2.4221 |
| 521 | 2.4318 | 431 | 2.4953 |
| 422 | 2.4302 | 332 | 2.4770 |
| 223 | 2.4133 | 133 | 2.4285 |
| 513 | 2.4589 | | |
| 033 | 2.4437 | | |

As described above, when a sum of each mode is used as a heating profile and frequency swept, a hot zone and a cold zone are mixed, thereby implementing a more uniform E-field.

In an embodiment, the microwave power generator 540 sweeps a set bandwidth multiple times. If a sweep from 2.4 GHz to 2.5 GHz is set at 1 msec, each frequency will pass 1,000 times during a 1 second operation. As compared with the above-described example, when a band width is increased from swept from 2.3 GHz to 2.6 GHz, the number of modes is further increased, and thus the hot zone and the cold zone are further increased, and thus the heating uniformity is further increased.

According to an embodiment of the inventive concept, the gallium nitride (GaN)-based solid state device is used as a microwave power generator to enable a frequency sweep. Through the frequency sweep, more modes are generated in a given cavity (e.g., box shape, cylindrical shape) so that hot spots and cold spots are mixed, thereby improving a final temperature uniformity.

The microwave application unit 500 functions as a heating source for transferring an energy for heating to the substrate W. In addition, the microwave application unit 500 functions as a plasma source. The microwave application unit 500 generates a plasma by applying a microwave to a reaction gas at the inner space 105. Therefore, according to an embodiment of the inventive concept, a plasma treatment and a heating (e.g., rapid heating annealing) are possible in one chamber.

Furthermore, according to the substrate treating apparatus according to an embodiment of the inventive concept, it may be sufficient without providing a separate annealing chamber, and thus a footprint of one chamber facility can be reduced. In addition, since a step of moving between a device using a plasma and an annealing device is unnecessary, a moving time between devices may be removed, thereby increasing a UPH. The substrate treating apparatus according to an embodiment of the inventive concept may be applied to an ALE process.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a process chamber having a treating space therein for treating a substrate;
a substrate support unit configured to support the substrate in the treating space; and
a microwave application unit configured to apply a microwave to the treating space, and
wherein the microwave application unit comprises a microwave power generator based on a solid state device.

2. The substrate treating apparatus of claim 1, wherein the solid state device comprises a gallium nitride (GaN) device.

3. The substrate treating apparatus of claim 1, wherein the microwave power generator may shift or sweep a frequency of the microwave.

4. The substrate treating apparatus of claim 1, wherein the microwave power generator is capable of sweeping a microwave having a first bandwidth between a first frequency and a second frequency which is higher than the first frequency.

5. The substrate treating apparatus of claim 4, wherein the microwave power generator sweeps the microwave having the first bandwidth a plural number of times.

6. The substrate treating apparatus of claim 1, wherein the microwave power generator sweeps a microwave having a first bandwidth between a first frequency and a second frequency which is higher than the first frequency, and a sum of a plurality of modes is a heating profile, and
wherein the plurality of modes are determined in a different number according to a shape of the treating space.

7. The substrate treating apparatus of claim 1, wherein the microwave power generator sweeps a microwave having a first bandwidth between a first frequency and a second frequency which is higher than the first frequency, and a sum of a plurality of modes is a heating profile, and
wherein the plurality of modes are determined in a different number according to a width of the first bandwidth.

8. The substrate treating apparatus of claim 1, wherein the microwave application unit comprises:
a microwave antenna in a plate shape positioned above the substrate support unit;
a dielectric plate positioned on top of and beneath the microwave antenna; and
an antenna rod transmitting a microwave generated at the microwave power generator to the microwave antenna.

9. The substrate treating apparatus of claim 8, wherein the microwave application unit functions as a heating source for transmitting an energy for heating to the substrate.

10. The substrate treating apparatus of claim 8, further comprising a gas supply unit for supplying a reaction gas to the treating space, and
wherein microwave application unit functions as a plasma source for exciting the reaction gas to a plasma state.

11.-19. (canceled)

20. A substrate treating apparatus comprising:
a process chamber having a treating space therein for treating a substrate;
a substrate support unit configured to support the substrate in the treating space;
a microwave application unit configured to apply a microwave to the treating space, and
wherein the microwave application unit comprises a microwave power generator based on a gallium nitride (GaN) solid state device, and
wherein the microwave power generator sweeps a plurality of target sweeping frequencies existing at a first bandwidth between a first frequency and a second frequency which is higher than the first frequency, and
wherein the number of target sweeting frequencies is determined differently according to a shape of the treating space and a width of the first bandwidth.
